(19) United States
(12) Patent Application Publication
(10) Pub. No.: US 2013/0187295 A1
(43) Pub. Date: Jul. 25, 2013

(54) SENSOR MODULE, PRODUCTION METHOD OF A SENSOR MODULE, AND INJECTION MOLD FOR ENCAPSULATING A SENSOR MODULE

(71) Applicants: Willibald Reitmeier, Hohenschambach (DE); Andreas Wildgen, Nittendorf (DE)

(72) Inventors: Willibald Reitmeier, Hohenschambach (DE); Andreas Wildgen, Nittendorf (DE)

(73) Assignee: Continental Automotive GmbH, Hannover (DE)

(21) Appl. No.: 13/512,295

(22) PCT Filed: Nov. 26, 2010
(86) PCT No.: PCT/EP2010/068340

§ 371 Date: Sep. 20, 2012

(30) Foreign Application Priority Data
Nov. 26, 2009 (DE) 10 2009 055 718.0

(51) Int. Cl. H01L 21/56; H01L 23/28

(52) U.S. Cl. CPC H01L 21/56; H01L 23/28
USPC 257/787; 438/127; 425/121

(57) ABSTRACT

A sensor module an injection mold for covering the sensor module, and to a production method for a covered sensor module including a chip carrier and a sensor chip disposed thereon. A channel is formed between the chip carrier and the sensor chip, by which a medium can be fed to the sensor chip.

### CROSS REFERENCE TO RELATED APPLICATIONS

This is a U.S. national stage of application No. PCT/EP2010/068340, filed on 26 Nov. 2010. Priority is claimed on German Application No. 10 2009 055 718.0 filed 26 Nov. 2009, the content of which is incorporated here by reference.

### BACKGROUND OF THE INVENTION

1. Field of the Invention

The present invention relates to a sensor module, an injection mold for encapsulating a sensor module, and a method for producing a sensor module.

2. Description of Prior Art

Sensor modules have a chip carrier, referred to as a lead frame, and a sensor chip on the chip carrier. The sensor chip is electrically connected to the chip carrier. In order to protect the sensor chip against external influences, the sensor module is at least partly encapsulated with a plastic material.

Such a sensor module and a method for producing this sensor module are described in DE 10 2007 057 903 A1. The sensor module has a sensor chip applied on a lead frame, said sensor chip having a sensor area. The sensor chip is fixed on a forked holding section of the lead frame such that the sensor area is on that side of the sensor chip which faces the lead frame. On account of the forked configuration of the lead frame, the lead frame is situated only at the outer sides of the sensor chip.

A covering of the sensor module is formed in a transfer molding process, wherein the covering material is introduced into an injection mold at a pressure of less than 10 bar. After filling the injection mold, a repressing process can be carried out, in which the covering material is subjected to a pressure of between 50 and 100 bar to force residual air out of the injection mold.

In order not to concomitantly cover the sensor area during the transfer molding process, DE 10 2007 057 903 A1 describes arranging a cannula along a side of the leadframe that faces away from the sensor chip. The cannula is secured by an adhesive film during encapsulation and the sensor area is covered by means of the adhesive film.

One disadvantage of such a method for producing a sensor module is that the sensor chip and/or the sensor area can be damaged or destroyed by the pressure exerted on the sensor chip and/or the sensor area by the injection mold. Furthermore, air bubbles can be introduced during the filling of the injection mold with the covering material and pressure differences can occur in the injection mold, which can lead to damage or destruction of the sensor chip. This applies particularly if structural cavities are present at the sensor chip or the sensor module is intended to be covered only on one side.

### SUMMARY OF THE INVENTION

An object of the present invention, therefore, is to provide a sensor module optimized in comparison with the prior art with regard to a process for producing the sensor module, and also to specify a corresponding injection mold for encapsulating a sensor module and a method for producing a corresponding sensor module.

A sensor module according to one embodiment of the invention comprises a chip carrier (lead frame), having a first side and a second side opposite the first side, a sensor chip arranged at least partly on the first side of the chip carrier (lead frame) and which can be electrically supplied by the chip carrier (lead frame), and a channel arranged between the sensor chip and the chip carrier (lead frame), by which channel a medium can be fed to the sensor chip.

A sensor module comprises a chip carrier (lead frame) having a first and a second side. The first and second sides are opposite one another. A sensor chip is at least partly arranged on the first side of the chip carrier. The sensor chip is electrically supplied via the chip carrier. Furthermore, the chip carrier can be electrically connected to the sensor chip such that it forwards electrical signals of the sensor chip.

A channel is arranged between the sensor chip and the chip carrier. A medium, for example air, can be fed to the sensor chip by said channel. The sensor chip performs the task of a wall of the channel. The channel can be formed by embossing in the chip carrier; in particular, the channel can be led out along the chip carrier to a connection side of the sensor module.

One advantage of this sensor module is that a medium to be measured passes merely via the channel to the sensor chip on account of the arrangement of chip carrier and sensor chip. In particular, a sensor region of the sensor chip is not exposed directly to the medium to be measured.

By way of example, this advantage is elucidated on the basis of the use of the sensor module in a motor vehicle. In this case, the sensor module is a pressure sensor module. The pressure sensor module is arranged in a line of the motor vehicle such that an opening of the channel is preferably situated on a flow-remote side of the sensor module. As already set out above, in this way a sensor region of the sensor chip is not exposed directly to the medium to be measured.

A resultant advantage is a reduced contamination of the sensor chip, as a result of which the durability of the sensor module is increased. Contamination can furthermore lead to a deterioration in measurement performance of the sensor module. The construction of the sensor module with a channel between sensor chip and chip carrier, as set out above, reduces a sensor drift on account of contamination.

In one preferred embodiment, the channel extends from the first side of the chip carrier to the second side of the chip carrier. The channel can extend firstly via a first section on the first side of the chip carrier between the chip carrier and the sensor chip. After the first segment, the channel extends through the chip carrier from the first side to the second side of the chip carrier. Since the first side is opposite the second side of the chip carrier, a through passage through the chip carrier is formed in this way. An opening of the channel, for example when this sensor module is used in a line of a motor vehicle, lies on a flow-remote side of the sensor module, as already set out above.

It is furthermore advantageous if the chip carrier is a lead frame or a printed circuit board. Depending on the requirements made of the sensor module, the channel can be formed in a lead frame or in a printed circuit board. Both the lead frame and the printed circuit board fulfill the functions of the chip carrier as set out above.

It is particularly preferred for the sensor chip to have two sensor regions opposite one another, wherein one of the sensor regions can be connected to the environment of the sensor module via the channel. Such a sensor chip is a differential pressure sensor having a membrane. The membrane is deflected on account of a pressure difference between a first and a second side and outputs a corresponding electrical signal.

It is furthermore advantageous if the sensor module at least partly has a covering. The covering consists of a plastic material, whereby the sensor module, in particular the sensor chip, is at least partially covered. In this way, the sensor module and/or the sensor chip are/is protected against influences by a medium surrounding the sensor module.

The channel of the sensor module preferably extends through the covering. A sensor module covered with a plastic material can thus furthermore detect, a pressure from a flow-remote side of the sensor module, as described above. Furthermore, a covered sensor module having the channel has the advantages mentioned above.

An injection mold according to the invention for covering a sensor module according to one embodiment of the invention has two mold halves, wherein at least one of the mold halves has an opening, such that a channel of the sensor module, said channel being formed between a chip carrier (lead frame) and a sensor chip, can be connected to an environment of the injection mold via said opening.

The injection mold consists of two mold halves, for example an upper and a lower mold half. One of the two mold halves has an opening. The opening is opposite an opening of a channel of a sensor module when the sensor module is arranged in the mold half. Consequently, the channel present between sensor chip and sensor module can be connected to an environment of the injection mold, for example to the air surrounding the injection mold.

During encapsulation of the sensor module, on account of the above arrangement, a medium can be fed to the channel and thus to the sensor chip via the opening in the mold half. Via the opening in the mold, a reference medium can also be fed to the sensor chip via the channel.

Advantageously, at least one of the mold halves has a film, while the injection mold furthermore has a device with which the film can be penetrated, such that the device can be connected to the channel of the sensor module. Films in injection molds are usually used to achieve easy separation of the covered sensor module produced from the mold halves in comparison with the mold halves without a film. A new film is inserted during each encapsulation process. Therefore, a device is required which penetrates the film anew in each covering step. Advantageously, using said device, the channel of the sensor module according to one embodiment of the invention can be vented or a reference medium can be fed. Furthermore, the device can be used to provide pressure equalization during the covering process. The device is, for example, a line which is pointed or whose end has been heated in order to penetrate the film.

A method for producing a covered sensor module, in particular a sensor module according to one embodiment of the invention, has the following steps: providing a sensor module by arranging a sensor chip on a first side of a chip carrier (lead frame), wherein a channel is formed between the sensor chip and the chip carrier, introducing the sensor module into an injection mold having two mold halves, in particular an injection mold according to the invention, introducing a device into the injection mold, such that the device is connected to the channel of the sensor module, and at least partly covering the sensor module with a covering material.

Firstly, a sensor module according to the invention as described above is provided. The sensor module has a channel between a chip carrier and a sensor chip arranged on a first side of the chip carrier. Said sensor module has all the advantages set out above. Therefore, these advantages will not be set out again here.

The sensor module is subsequently introduced into an injection mold according to one embodiment of the invention. A first or a second mold half of the injection mold has an opening as described above. The opening in one of the mold halves is formed such that it is opposite an opening of the channel of the sensor module. By way of example, the opening is formed in a lower mold half of the injection mold. The advantages of the injection mold according to the invention have likewise being described above and will therefore not be explained again at this juncture.

After the sensor module has been introduced into the injection mold, a device is introduced into the opening in one of the mold halves. The device can be introduced, for example, at the same time as or after the injection mold is closed. The device is introduced into the opening to such an extent that it is connected to the channel of the sensor module.

After the injection mold has been completely closed, the sensor module is at least partly covered with a covering material, for example with a plastic. If that side of the sensor module which has an opening of the channel is also intended to be covered, the device connected to the channel is used for preventing, at least initially, the channel from being closed with the covering material.

This production method can be used to produce a sensor module according to one embodiment of the invention, which is at least partially covered. The covering can be effected on one side or on both sides. In particular, in this way, sensor chips having a membrane and/or structural cavities can be covered with a covering material on one side with greater process reliability in comparison with the prior art. This concerns, in particular, sensor chips such as, for example, the differential pressure sensor mentioned above.

Advantageously, at least one of the mold halves used has a film. On account of the film, the covered sensor module can be separated particularly easily from the injection mold in comparison with a conventional injection mold. Furthermore, the film performs sealing tasks during the covering step.

In a preferred embodiment, the production method furthermore has the following steps: penetrating the film by the device, with the result that an opening is created in the film, and introducing a medium into the channel by the device.

The device is a hollow body having a tip to penetrate the film. With the aid of the device, it is possible to effect pressure equalization during the covering step at the sensor chip or the channel can be filled with a reference medium.

In one advantageous embodiment, the device is also withdrawn from the channel during the covering step. A closed covering can be produced in this way. This is preferred particularly when the channel is filled with a reference medium.

### BRIEF DESCRIPTION OF THE DRAWINGS

The present invention is described in a detailed manner below with reference to the drawings. Identical reference signs in the drawings designate identical elements.

In the figures:

FIG. 1 is a schematic illustration of a section through an injection mold with a sensor module during a process for covering the sensor module.

FIG. 2 is a schematic illustration of a section through a sensor module according to the invention and an injection mold according to the invention after a covering process, and

FIG. 3 is a schematic method sequence of a production method according to one embodiment of the invention.

### DETAILED DESCRIPTION OF THE PREFERRED EMBODIMENTS

The sensor module according to the invention is used in a motor vehicle, for example. The sensor chip is a differential pressure sensor, for example, which is arranged in an airflow of the motor vehicle.

Referring to FIG. 1, a sensor module comprises a chip carrier 110 (lead frame) and also a sensor chip 120 arranged on a first side of the chip carrier 110. The sensor chip 120 has a structural cavity 122. By way of example, a membrane is arranged in said cavity 122.

The sensor module is introduced into an injection mold consisting of a lower mold half 130 and an upper mold half 132. Both mold halves have a film 134. The film 134 facilitates later release of the sensor module from the injection mold.

In the closed state of the mold halves, a projection 136 in the upper mold half 132 covers the structural cavity 122 of the sensor chip 120. In the closed state, the projection 136 can exert a pressure on the sensor chip 120 which causes damage to or destruction of the sensor chip 120. In particular, in the example in accordance with FIG. 1, the structural cavity 122 would be affected, and thus also a membrane arranged in the cavity 122.

To cover the sensor module, in FIG. 1 precisely a covering material 140 is introduced into the injection mold, for example a plastic. The covering material 140 covers both a lower side of the sensor module and an upper side. During the introduction of the covering material 140 into the injection mold or during a repressing process, pressure differences can occur on account of air inclusions in the covering material 140. Said pressure differences can damage or destroy the sensor chip 120, in particular a membrane of the sensor chip 120.

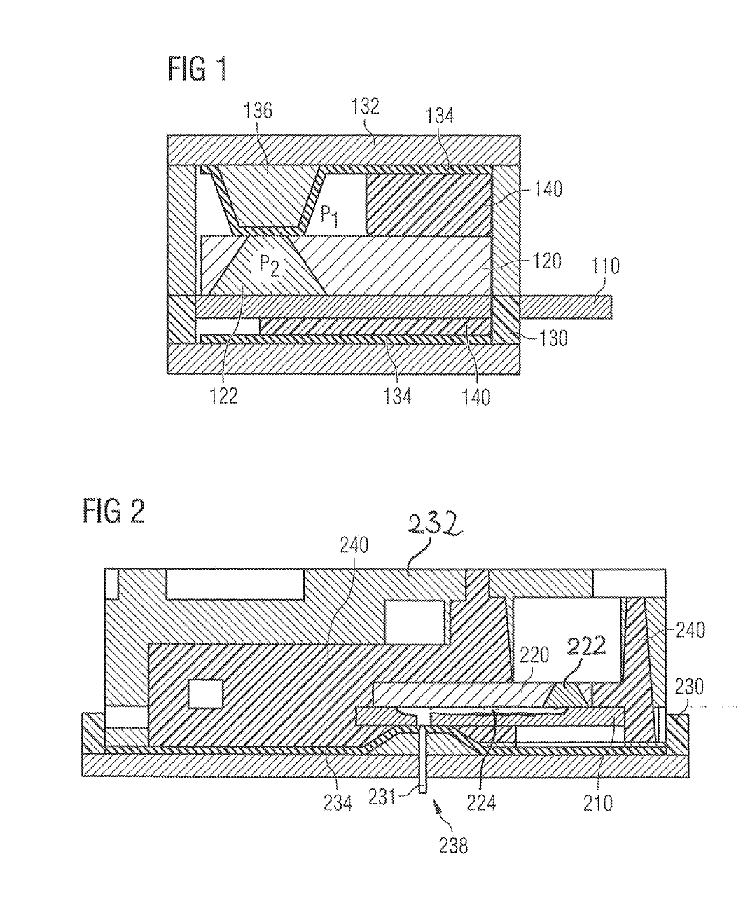

In FIG. 2, a lower mold half 230 has an opening 231, into which a device 238 is introduced. The device 238 is a pointed hollow body, for example. A film 234 is penetrated by the device 238.

As in FIG. 1, too, a sensor module is situated in the lower mold half 230 in FIG. 2 as well. Said sensor module has a channel 224 between a sensor chip 220 and a chip carrier 210. The channel 224 extends from the device 238 as far as a structural cavity 222 of the sensor chip 220. For this purpose, the channel 224 proceeding from the device 238 firstly penetrates the chip carrier 210 and then extends along the first side of the chip carrier 210 as far as the cavity 222. The sensor chip 220 constitutes a wall of the channel 224, for example. Furthermore, the channel 224 may have been formed by embossing in the chip carrier 210. By way of example, a membrane can be arranged in the cavity 222, such that the cavity constitutes a sensor region of the sensor chip 220. The sensor chip 220 is a differential pressure sensor chip, in particular.

By the device 238, pressure equalization can be effected during covering of the sensor module. Furthermore, a reference medium can be fed to the channel 224. In FIG. 2, the film 234 of the lower mold half 230 bears around an opening of the channel 224 on the chip carrier 210, such that no covering with covering material 240 takes place at this location. The sensor chip 220 has a structural cavity 222. A membrane, for example, is arranged in said cavity 222.

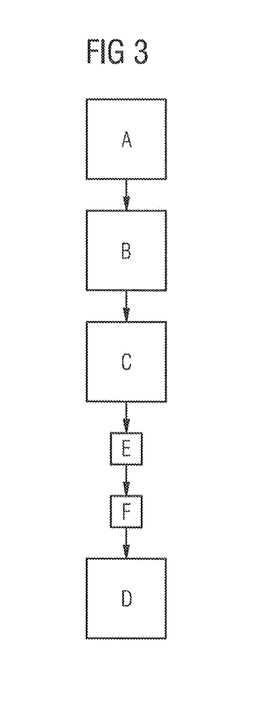

Referring to FIG. 3, a sensor module according to one embodiment of the invention is provided in a step A. The sensor module includes a chip carrier 210, on the first side of which a sensor chip 220 is arranged. A channel 224 is formed between the sensor chip 220 and the chip carrier 210.

Said sensor module is introduced into an injection mold having two mold halves 230, 232 in a step B. The injection mold has a film 234, for example. Furthermore, one of the mold halves 230, 232, for example a lower mold half 230, has an opening 231.

In a step C, a device 238 is introduced into the opening 231 of the lower mold half 230 of the injection-molding device. At the same time or beforehand, the injection mold is closed by an upper mold half 232 being placed onto the lower mold half 230. With the aid of the closing of the mold halves 230, 232, a film 234 is fixedly held in the injection mold.

The film 234 is penetrated by the device 238 in a step E. After penetration, the device 238 is connected to the channel 224, the opening of which is arranged above the opening 231 in the lower mold half 230. The device 238 is, in particular, a pointed hollow body.

In a step F, a medium is introduced into the channel 224 via the device 238, for example air or a reference medium. The medium is introduced during or after the injection mold has been completely closed. The introduction of the medium generates a pressure in the channel 224, which is intended to counteract a pressure caused by the injection mold or on account of a covering step. The pressure in the channel 224 can be a predetermined, driven pressure value or it can be a regulated pressure value which in each case counteracts the pressure applied by the injection mold.

The covering of the sensor module with a covering material is effected in a step D. During covering, the device 238 can be withdrawn from the sensor module, such that a covering is also formed above an opening of the channel 224. This is particularly advantageous if the channel 224 is filled with a reference medium.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-13. (canceled)

14. A sensor module comprising:
a chip carrier having a first side and a second side opposite the first side;
a sensor chip arranged at least partly on the first side of the chip carrier and is electrically supplied by the chip carrier; and
a channel arranged between the sensor chip and the chip carrier by which a medium is fed to the sensor chip.

15. The sensor module as claimed in claim 14, wherein the channel extends from the first side of the chip carrier to the second side of the chip carrier.

16. The sensor module as claimed claim 15, wherein the chip carrier is a printed circuit board.

17. The sensor module as claimed claim 14, wherein the sensor chip has two sensor regions opposite one another, wherein one of the sensor regions can be connected to an environment of the sensor module via the channel.

18. The sensor module as claimed in claim 14, further comprising at least a partial covering.

19. The sensor module as claimed in claim 18, wherein the channel extends through the covering.

20. An injection mold for covering a chip carrier having a first side and a second side opposite the first side, a sensor chip arranged at least partly on the first side of the chip carrier and is electrically supplied by the chip carrier, and a channel arranged between the sensor chip and the chip carrier by which a medium is fed to the sensor chip, comprising:
a first mold half; and
a second mold half,
wherein at least one of the mold halves has an opening, such that the channel being formed between the chip carrier and the sensor chip is connected to an environment of the injection mold via the opening.

21. The injection mold as claimed in claim 20, further comprising:
a film of at least one of the mold halves; and
a device with which the film is penetrated such that the device is connected to the channel of the sensor module.

22. A method for producing a covered sensor module having a chip carrier with a first side and a second side opposite the first side, a sensor chip arranged at least partly on the first side of the chip carrier and is electrically supplied by the chip carrier, and a channel arranged between the sensor chip and the chip carrier by which a medium is fed to the sensor chip, the method comprising:
arranging the sensor chip on the first side of the chip carrier, wherein the channel is formed between the sensor chip and the chip carrier;
introducing the sensor module into an injection mold having two mold halves;
introducing a device into the injection mold such that the device is connected to the channel of the sensor module; and
at least partly covering the sensor module with a plastic material.

23. The method as claimed in claim 22, wherein at least one of the mold halves has a film.

24. The production method as claimed in claim 23, further comprising:
penetrating the film by the device to create an opening in the film; and
introducing a medium into the channel by the device.

25. The production method as claimed in claim 24, further comprising filling the channel with a reference medium via the device.

26. The production method as claimed in claim 24, wherein the device is withdrawn during the covering of the sensor module.

27. The production method as claimed in claim 25, wherein the device is withdrawn during the covering of the sensor module.
